(19) United States
(12) Patent Application Publication
(10) Pub. No.: US 2024/0429186 A1
(43) Pub. Date: Dec. 26, 2024

(54) BONDING STRUCTURE AND STACK TYPE SEMICONDUCTOR DEVICE INCLUDING THE SAME

(71) Applicant: SK hynix Inc., Gyeonggi-do (KR)

(72) Inventor: Byung Ho LEE, Gyeonggi-do (KR)

(21) Appl. No.: 18/505,125

(22) Filed: Nov. 9, 2023

(30) Foreign Application Priority Data
Jun. 22, 2023 (KR) 10-2023-0080433

(51) Int. Cl. H01L 23/00

(52) U.S. Cl. CPC H01L 24/08; H01L 24/06; H01L 2224/06177; H01L 2224/08145

(57) ABSTRACT

A bonding structure may include a bonding surface in which components may be integrated. The bonding surface may include a first bonding region, a second bonding region and at least one bonding wiring. The first bonding region may include a plurality of first bonding pads and a first bonding insulation layer. The first bonding pads may be distributed in a first density. The first bonding insulation layer may be positioned between the first bonding pads. The second bonding region may include a plurality of second bonding pads and a second bonding insulation layer. The second bonding pads may be distributed in a second density less than the first density. The second bonding insulation layer may be positioned between the second bonding pads. The bonding wiring may be exposed toward the bonding surface in the second bonding region. The bonding wiring may receive a voltage from an external device.

### CROSS-REFERENCES TO RELATED APPLICATION

The present application claims priority under 35 U.S.C. § 119 (a) to Korean application number 10-2023-0080433, filed on Jun. 22, 2023, which is incorporated herein by reference in its entirety.

### BACKGROUND

### 1. Technical Field

Various embodiments of the present disclosure generally relate to a bonding structure and a stack type semiconductor device including the same, more particularly, to a bonding structure and a stack type semiconductor device including the bonding structure.

### 2. Related Art

As a size of an electronic device has reduced, a size of each of the dies in a wafer has been decreasing. Further, in order to provide an electronic device with a large capacity, the dies have been stacked to form an assembly.

In order to effectively assemble the dies having a small size, a plurality of the wafers have been directly bonded to each other by a hybrid bonding process.

The hybrid bonding may be a fusion bonding or a direct bonding. In the hybrid bonding process, the dies or the wafers may be directly bonded to each other without a middle layer therebetween.

For example, when a first wafer and a second wafer may be hybrid-bonded to each other, first bonding pads and a first bonding insulation layer of the first wafer and second bonding pads and a second bonding insulation layer of the second wafer may be directly bonded to each other.

Arrangements of the first and second bonding pads may be different from each other in accordance with the types of components on the first and second wafers. Further, integration densities of the bonding pads by regions of each of the wafers may also be different from each other in accordance with the types of components on the first and second wafers.

### SUMMARY

According to various embodiments of the present disclosure, there may be provided a bonding structure. The bonding structure may include a bonding surface in which components may be integrated. The bonding surface may include a first bonding region, a second bonding region and at least one bonding wiring. The first bonding region may include a plurality of first bonding pads and a first bonding insulation layer. The first bonding pads may be distributed in a first density. The first bonding insulation layer may be positioned between the first bonding pads. The second bonding region may include a plurality of second bonding pads and a second bonding insulation layer. The second bonding pads may be distributed in a second density less than the first density. The second bonding insulation layer may be positioned between the second bonding pads. The bonding wiring may be arranged at the second bonding region. The bonding wiring may be configured to receive and transfer a voltage from an external device.

According to other embodiments of the present disclosure, there may be provided a stack type semiconductor device. The stack type semiconductor device may include a first structure and a second structure. The first structure may include a first bonding region and a second bonding region. The first bonding region may include a plurality of first bonding pads and a first bonding insulation layer positioned between the first bonding pads. The second bonding region may include at least one second bonding pad, a second bonding insulation layer and at least one first bonding wiring. The second bonding insulation layer may insulate the second bonding pad. The first bonding wiring may be positioned in the second bonding insulation layer. The second structure may include a third bonding region and a fourth bonding region. The third bonding region may include a plurality of third bonding pads and a third bonding insulation layer. The third bonding pads may be hybrid-bonded to the first bonding pads. The third bonding insulation layer may be hybrid-bonded to the first bonding insulation layer. The fourth bonding region may include at least one fourth bonding pad, a fourth bonding insulation layer and at least one second bonding wiring. The fourth bonding pad may be hybrid-bonded to the second bonding pad. The fourth bonding insulation layer may be hybrid-bonded to at least one of the first bonding wirings. The second bonding wiring may be hybrid-bonded to at least one of the first bonding wiring and the second bonding insulation layer.

According to still other embodiments of the present disclosure, there may be provided a stack type semiconductor device. The stack type semiconductor device may include a first die and a second die hybrid-bonded to the first die. The first die may include a first bonding region, a second bonding region and at least one bonding wiring. The first bonding region may include a plurality of bonding pads distributed by a first density. The second bonding region may have a first region and a second region. The bonding pads may be distributed in the first region by a second density less than the first density. The bonding pads may not be arranged in the second region. The first bonding wiring may be arranged in the second region. The first bonding wiring may be hybrid-bonded to the second die to transmit an electrical signal. The second die may include a third bonding region, a fourth bonding region and at least one second bonding wiring. The third bonding region may include a plurality of bonding pads hybrid-bonded to the bonding pads of the first die. The fourth bonding region may include a plurality of bonding pads arranged by a density less than a density of the bonding pads in the third region. The second bonding wiring may be arranged in a selected portion of the fourth bonding region. The second bonding wiring may be hybrid-bonded to the second bonding region to transmit an electrical signal.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a perspective view illustrating a stack type semiconductor device in accordance with various embodiments of the present disclosure;

FIG. 2 is a plan view illustrating a first structure of a stack type semiconductor device in accordance with other embodiments of the present disclosure;

FIG. 3 is a plan view illustrating a second structure of a stack type semiconductor device in accordance with still other embodiments of the present disclosure;

FIG. 4 is a plan view illustrating hybrid-bonded bonding surfaces of first and second structures in accordance with yet other embodiments of the present disclosure;

FIG. 5 is a cross-sectional view taken along a line x1-x1′ in FIG. 4;

FIGS. 6A and 6B are a flow chart illustrating a hybrid-bonding process in accordance with various embodiments of the present disclosure;

FIG. 7 is a plan view illustrating a first structure of a stack type semiconductor device in accordance with other embodiments of the present disclosure;

FIG. 8 is a plan view illustrating a second structure of a stack type semiconductor device in accordance with still other embodiments of the present disclosure;

FIG. 9 is a plan view illustrating hybrid-bonded bonding surfaces of first and second structures in accordance with yet other embodiments of the present disclosure;

FIG. 10 is a cross-sectional view taken along a line x2-x2′ in FIG. 9;

FIG. 11 is a plan view illustrating a first die of a stack type semiconductor device in accordance with further embodiments of the present disclosure;

FIG. 12 is a plan view illustrating a second die of a stack type semiconductor device in accordance with various embodiments of the present disclosure;

FIG. 13 is a plan view illustrating hybrid-bonded bonding surfaces of first and second dies in accordance with other embodiments of the present disclosure; and

FIG. 14 is a cross-sectional view taken along a line x3-x3′ in FIG. 13.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but include deviations to configurations and shapes described herein.

The present invention is described herein with reference to cross-section and/or plan illustrations of the embodiments of the present invention. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and scope of the present disclosure.

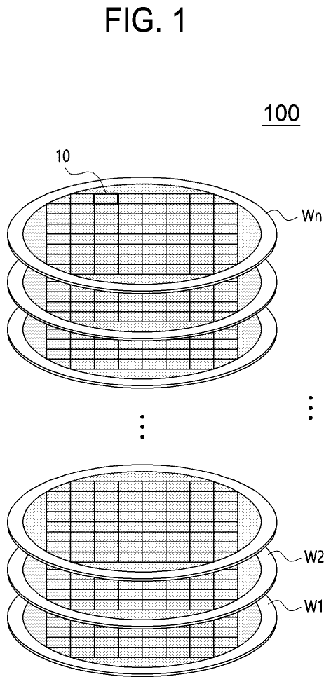

FIG. 1 is a perspective view illustrating a stack type semiconductor device in accordance with various embodiments of the present disclosure.

As noted above, integration densities of bonding pads on different wafers may be different from each other in accordance with the types of components on the different wafers. The difference between the integration densities of the bonding pads may cause a bonding error when hybrid bonding joins the two different wafers together. The present invention arises in this context.

Referring to FIG. 1, a stack type semiconductor device 100 may include at least two, for example, first to nth wafers W1˜Wn. Each of the wafers W1˜Wn may include an upper surface W_F and a lower surface W_B.

For example, each of the wafers W1˜Wn may include a plurality of dies 10. A plurality of circuit patterns may be integrated in each of the dies 10 on the upper surface W_F of the wafer to form an electronic component, for example, a memory component.

A plurality of bonding pads and a bonding insulation layer may be arranged on the upper surface W_F and the lower surface W_B of each of the wafers W1˜Wn. The bonding pads may be electrically connected with the circuit patterns.

For example, in order to directly bond an upper surface W_F of a lower wafer to a lower surface W_B of an upper wafer, the first to nth wafers W1˜Wn may be stacked. Alternatively, in order to directly bond an upper surface W_F of a lower wafer to an upper surface W_F of an upper wafer or a lower surface W_B of a lower wafer to a lower surface W_B of an upper wafer, the first to nth wafers W1˜Wn may be stacked.

Hereinafter, a wafer bonding surface or a bonding surface may correspond to the upper surface W_F or the lower surface W_B of the wafer, or bonded surfaces of the different wafers or structures.

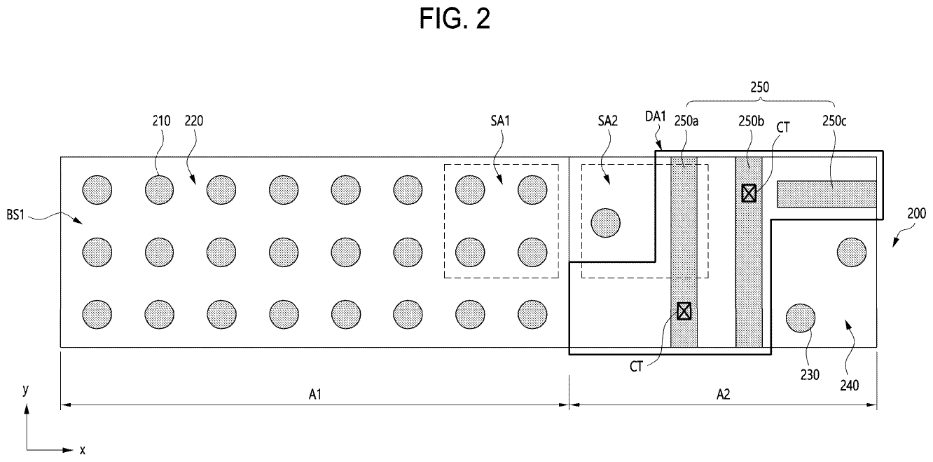

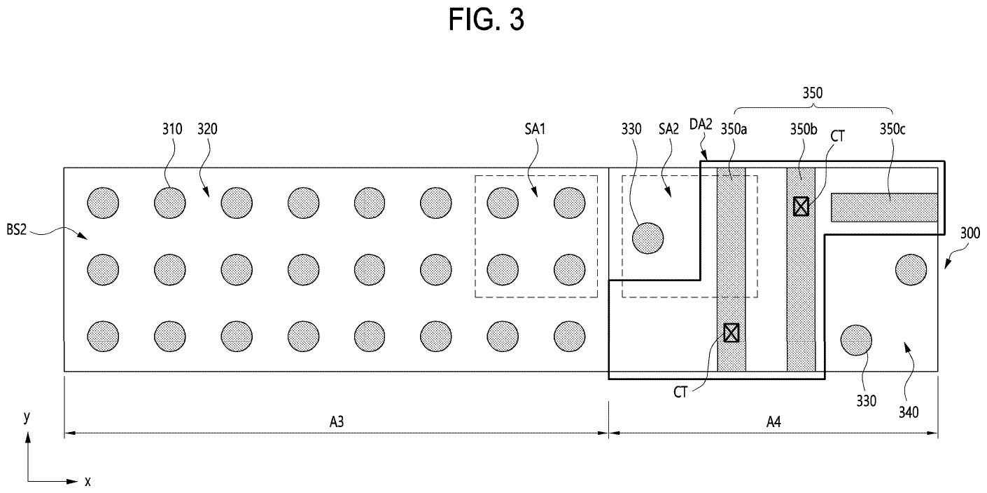

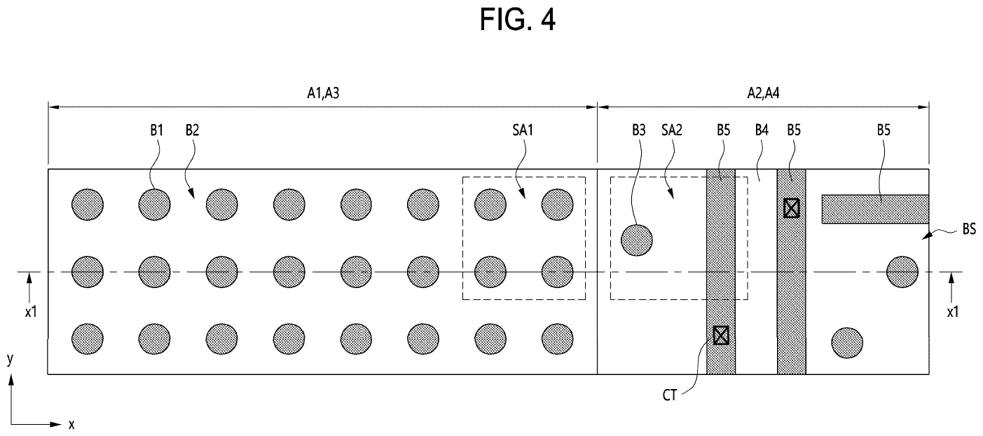

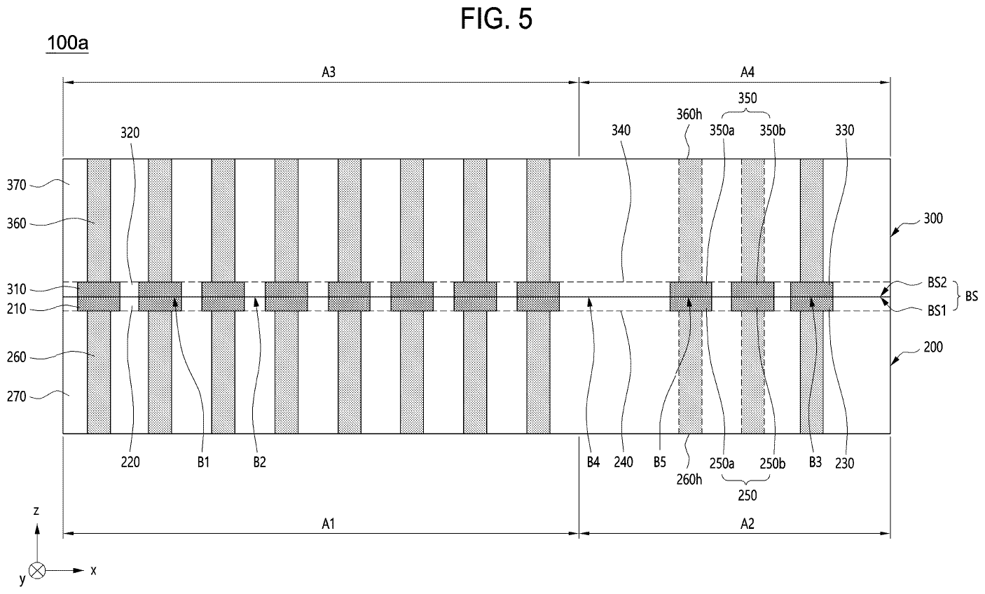

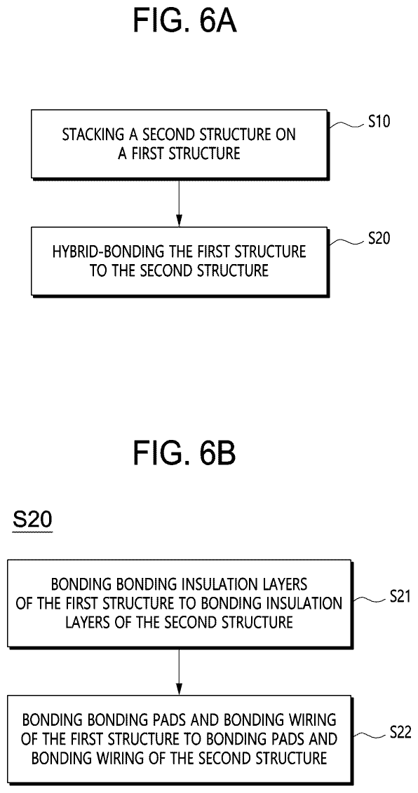

FIG. 2 is a plan view illustrating a first structure of a stack type semiconductor device in accordance with various embodiments of the present disclosure, FIG. 3 is a plan view illustrating a second structure of a stack type semiconductor device in accordance with other embodiments of the present disclosure, FIG. 4 is a plan view illustrating hybrid-bonded bonding surfaces of first and second structures in accordance with still other embodiments of the present disclosure, FIG. 5 is a cross-sectional view taken along a line x1-x1′ in FIG. 4, and FIGS. 6A and 6B are a flow chart illustrating a hybrid-bonding process in accordance with further embodiments of the present disclosure.

Referring to FIGS. 2 to 6B, a stack type semiconductor device 100a may include a first structure 200 and a second structure 300 hybrid-bonded to the first structure 200. For example, the first structure 200 and the second structure 300 may be a wafer, a part of a wafer, a die, etc. Further, each of the first and second structures 200 and 300 may include at least one electronic component with various circuit patterns. Each of the electronic components may include a plurality of conductive terminals.

The first structure 200 may include a first bonding surface BS1 bonded to the second structure 300, as shown in FIG. 5. The first bonding surface BS1 may include a first bonding region A1 and a second bonding region A2.

The first bonding region A1 may include a plurality of first bonding pads 210 and a first bonding insulation layer 220. The first bonding pads 210 may have a first density. The first bonding insulation layer 220 may be positioned between the first bonding pads 210. The first bonding pads 210 and the first bonding insulation layer 220 may be exposed at the first bonding surface BS1.

The second bonding region A2 may include a plurality of second bonding pads 230 and a second bonding insulation layer 240. The second bonding pads 230 may be exposed toward the first bonding surface BS1. The second bonding insulation layer 240 may be positioned between the second bonding pads 230. The second bonding pads 230 may have a second density lower than the first density for the first bonding pads 210.

The second bonding region A2 may further include at least one first bonding wiring 250. The first bonding wiring 250 may be positioned with the second bonding insulation layer 240 in between. The first bonding wiring 250 may be exposed at the first bonding surface BS1 similar to the second bonding pads 230 and the second bonding insulation layer 240.

In the depicted embodiment, the first bonding wiring 250 may be arranged in a region of the second bonding region A2 (where only the second bonding insulation layer 240 exists and the second bonding pads 230 are not arranged), for example, in a first dummy region DA1.

Alternatively, the second bonding pads 230 may be arranged in a region of the second bonding region A2 with the first bonding wiring 250, for example, in the first dummy region DA1.

An occupying ratio of the first bonding insulation layer 220 (based on a unit area SA1 of the first bonding region A1) may be similar to an occupying area of the second bonding insulation layer 240 (based on a unit area SA2 of the second bonding region A2) within an error range by the first bonding wiring 250. Here, the unit areas SA1 and SA2 can be set to an arbitrary size by architects. For example, the unit area SA1 of the first bonding region A1 and the unit area SA2 of the second bonding region A2 may be arbitrarily placed c. The unit area SA1 of the first bonding region A1 may be substantially the same as the unit area SA2 of the second bonding region A2.

Further, the occupying ratio of the first bonding insulation layer 220 (based on a unit area SA1 of the first bonding region A1) and the occupying area of the second bonding insulation layer 240 (based on a unit area SA2 of the second bonding region A2) may occupy, for example, about 50% to about 90% of the unit areas. For example, hybrid bonding errors can be prevented when the bonding insulation layers 220 and 240 occupy at least 50% of the unit areas SA1 and SA2. The unit areas SA1 and SA2 and the percentages may be changed in accordance with designs and process recipes.

For example, the first bonding wiring 250 may include a plurality of wirings. The first bonding wirings 250a˜250c may receive same signals or different signals. The first bonding wirings 250a˜250c may transmit the signals to a conductive terminal of the electronic component. Further, the first bonding wirings 250a˜250c may have various shapes and various widths in accordance with a shape of the first dummy region DA1 and in accordance with magnitudes of the received (and/or transfer) voltages. For example, the first bonding wirings 250a and 250b may be extended in an x-direction, and the first bonding wiring 250c may be extended in a y-direction, but the present invention is not limited thereto.

The first bonding wirings 250a, 250b and 250c may be operated as one or more of a signal compensation line, a power compensation line, an address transmission line, a reservoir capacitor, etc., in accordance with the received voltages. Further, the widths of the first bonding wirings 250a, 250b and 250c may be changed in accordance with the magnitudes of the received (and/or transfer) voltages.

The first bonding pad 210, the second bonding pad 230 and the first bonding wiring 250 may include the same conductive material, such as for example, at least one or more of Cu, W, Au, Ag and Al. The first and second bonding insulation layers 220 and 240 may include a dielectric material, such as for example, at least one or more of a silicon oxide layer, a silicon nitride layer, a silicon carbon nitride layer and a silicon carbon oxide layer. The first and second bonding insulation layers 220 and 240 may be extended on the first bonding surface BS1 without a disconnection.

Referring to FIG. 3, the second structure 300 may include a second bonding surface BS2 bonded to the first structure 200. The second bonding surface BS2 may include a third bonding region A3 and a fourth bonding region A4.

The third bonding region A3 may include a plurality of third bonding pads 310 and a third bonding insulation layer 320. The third bonding pads 310 may have a third density. The third bonding insulation layer 320 may be positioned between the third bonding pads 310. The third density may be substantially the same as the first density for the first bonding pads 210. The third bonding pads 310 and the third bonding insulation layer 320 may be exposed toward the second bonding surface BS2. For example, the third bonding pads 310 may correspond to the first bonding pads 210. Thus, the third bonding region A3 may correspond to a bonding pad concentration region together with the first bonding region A1.

The fourth bonding region A4 may include a plurality of fourth bonding pads 330 and a fourth bonding insulation layer 340. The fourth bonding pads 330 may be exposed toward the second bonding surface BS2. The fourth bonding insulation layer 340 may be positioned between the fourth bonding pads 330. The fourth bonding pads 330 may have a fourth density lower than the third density of bonding pads 310. For example, the fourth density may be substantially the same as the second density of second bonding pads 230. The fourth bonding pads 330 may be arranged corresponding to the second bonding pads 230.

Thus, the fourth bonding region A4 may include a second dummy region DA2 having a pattern density similar to the second bonding region A2. In various embodiments, at least one second bonding wiring 350 may be arranged in the second dummy region DA2 of the fourth bonding region A4. The second bonding wiring 350 may be arranged with the fourth bonding insulation layer 340 in between. The second bonding wiring 350 may be exposed toward the second bonding surface BS2.

In various embodiments, the second bonding wiring 350 may be arranged in a region of the fourth bonding region A4 with the fourth bonding pads 330 having a pattern layout forming, for example, the second dummy region DA2.

Alternatively, the fourth bonding pads 330 may be arranged in a region of the fourth bonding region A4 with the second bonding wiring 350 having a pattern layout forming, for example, the second dummy region DA2. For example, an occupying ratio of the third bonding insulation layer 320 (based on a unit area SA1 of the third bonding region A3) may be similar to an occupying area of the fourth bonding insulation layer 340 (based on a unit area SA2 of the fourth bonding region A4) within an error range by the second bonding wiring 350.

In other embodiments, the second bonding wiring 350 may include a plurality of wirings. The second bonding wirings 350a, 350b and 350c may be extended in the x-direction or the y-direction. The second bonding wirings 350a, 350b and 350c may be arranged corresponding to the first bonding wirings 250a, 250b and 250c. For example, the second bonding wirings 350a, 350b and 350c may have a width and a length substantially the same as a width and a length of the first bonding wirings 250a, 250b and 250c.

The second bonding wirings 350a, 350b and 350c may be operated as one or more of a signal compensation line, a power compensation line, an address transmission line, a reservoir capacitor, etc., of the electronic components integrated in the second structure 300.

The third bonding pad 310, the fourth bonding pad 330 and the second bonding wiring 350 may include a material substantially the same as the material of the first bonding pad 210, the second bonding pad 220 and the first bonding wiring 250, for example, at least one or more of Cu, W, Au, Ag and Al. The third and fourth bonding insulation layers 320 and 340 may include a dielectric material substantially the same as the first and second bonding insulation layers 220 and 240, for example, at least one of a silicon oxide layer, a silicon nitride layer, a silicon carbon nitride layer and a silicon carbon oxide layer. The third and fourth bonding insulation layers 320 and 340 may be extended on the second bonding surface BS2 without a disconnection.

In the disclosed embodiments shown in FIG. 5, the first structure 200 may further include a plurality of first interconnections 260. The first interconnections 260 may connect the conductive terminals of the electronic component in the first structure 200 with the first bonding pads 210, the second bonding pads 220 and the first bonding wiring 250. Further, the first structure 200 may further include a first insulating interlayer 270 configured to isolate the first interconnections 260 from each other.

The second structure 300 shown in FIG. 5 may further include a plurality of second interconnections 360. The second interconnections 360 may connect the electronic component in the second structure 300 with the third bonding pads 310, the fourth bonding pads 320 and the second bonding wiring 350. Further, the second structure 300 may further include a second insulating interlayer 370 configured to isolate the second interconnections 360 from each other.

The first and second interconnections 260 and 360 may be at least one through silicon via (TSV) and at least one vertical wiring structure configured to transmit voltages. The first and second interconnections 260 and 360 may include at least one insulation layer.

Further, the first bonding wiring 250 and the second bonding wiring 350 may make contact with the first and second interconnections 260 and 360 to transmit the voltage(s) to the corresponding electronic components. Further, when the first bonding wiring 250 is directly bonded to the second bonding wiring 350, electrical characteristics of the bonded electronic components can be compensated in ambi-direction. A reference numeral CT (such as shown in FIGS. 2 and 3 and 4) may indicate a contact of the interconnections 260 and 360 with the bonding wirings 250 and 350. The ambi direction means a direction with an angle difference of 180 degrees.

Referring to FIG. 6A, in process S10, the second structure 300 may be stacked on the first structure 200.

The first structure 200 and the second structure 300 may be stacked to face the bonding surfaces BS1 and BS2 of the first and second structures 200 and 300 to each other. Further, the first bonding region A1 of the first structure 200 may face the third bonding region A3 of the second structure 300. The second bonding region A2 of the first structure 200 may face the fourth bonding region A4 of the second structure 300.

As shown in FIG. 5, the first bonding pads 210 and the first bonding insulation layer 220 in the first bonding region A1 may face the third bonding pads 310 and the third bonding insulation layer 320 in the third bonding region A3. The second bonding pads 230 and the second bonding insulation layer 240 in the second bonding region A2 may face the fourth bonding pads 330 and the fourth bonding insulation layer 340 in the fourth bonding region A4. In process S20, the stacked first and second structures 200 and 300 may be hybrid-bonded to each other.

In the hybrid-bonding process, an insulation material of the first structure 200 may be directly bonded to an insulation material of the second structure 300 (with no intervening material that is different from the insulation materials). A conductive material of the first structure 200 may be directly bonded to a conductive material of the second structure 300 (with no intervening material that is different from the conductive materials).

Particularly, as shown in FIG. 6B, in process S21, the bonding insulation layers 220 and 240 of the first structure 200 may be directly bonded to the bonding insulation layers 320 and 340 of the second structure 300 (with no intervening materials that are different from the bonding insulation layers).

The first and second bonding insulation layers 220 and 240 of the first structure 200 corresponding to the dielectric layer may be directly bonded to the third and fourth bonding insulation layers 320 and 340 of the second structure 400 corresponding to the dielectric layer (with no intervening materials that are different from the dielectric layer and the bonding insulation layers). For example, surfaces of the first and second bonding insulation layers 220 and 240 of the first structure 200 and surfaces of the third and fourth bonding insulation layers 320 and 340 may be treated using plasma. A pressure may be applied to the first and second structures 200 and 300 to directly bond the first and second bonding insulation layers 220 and 240 to the third and fourth bonding insulation layers 320 and 340.

In further embodiments, a bonding area between the first bonding insulation layer 220 and the third bonding insulation layer 320 may be similar to a bonding area between the second bonding insulation layer 240 and the fourth bonding insulation layer 340 by the first and second bonding wirings 250 and 350. Thus, the first and second structure 200 and 300 may be directly bonded to each other in a dielectric versus dielectric bonding by a uniform bonding condition at any positions across the bonding areas. In this embodiment, the bonding condition may include both the plasma and the pressure, but the present invention is not limited thereto.

In process S22, the bonding pads 210 and 230 and the first bonding wiring 250 of the first structure 200 may be directly bonded to the bonding pads 310 and 320 and the second bonding wiring 350 of the second structure 300 (with no intervening materials that are different from the bonding pads and the bonding wiring).

Particularly, the first bonding pads 210, the second bonding pads 230, the first bonding wiring 250, the third bonding pads 310, the fourth bonding pads 330 and the second bonding wiring 350 corresponding to the conductive layers of the first and second structures 200 and 300 may be thermally cohered to each other in a temperature heating process.

The conductive layers of the first and second structures 200 and 300 may be thermally expanded to form a conductive layer versus a conductive layer bonding of the first and second structures 200 and 300.

In FIG. 4, B1 is a bonding surface between the first bonding pads 210 and the third bonding pads 310. B2 is a bonding surface between the first bonding insulation layer 220 and the third bonding insulation layer 320. B3 is a bonding surface between the second bonding pads 230 and the fourth bonding pads 330. B4 is a bonding surface between the second bonding insulation layer 240 and the fourth bonding insulation layer 340. B5 is a bonding surface between the first bonding wiring 250 and the second bonding wiring 350. BS is a surface to be cohered between the first bonding surface BS1 and the second bonding surface BS2.

In further embodiments, the first bonding wiring 250 and the second bonding wiring 350 may be arranged in the dummy regions of each of the structures to secure a bonding uniformity. Further, the first and second bonding wirings 250 and 350 may continuously receive the voltage to provide the electronic components with a voltage as a signal, an address or a power. The first and second bonding wirings 250 and 350 may be operated as the reservoir capacitor for improving operational characteristics of the electronic component. Therefore, the electronic components in the first and second structures 200 and 300 may have improved electrical characteristics.

Other embodiments may provide the bonding wirings having the same shape in each of the dummy regions DA1 and DA2. Alternatively, the bonding wirings 250 and 350 may be selectively bonded by the bonding structures 250b and 350b.

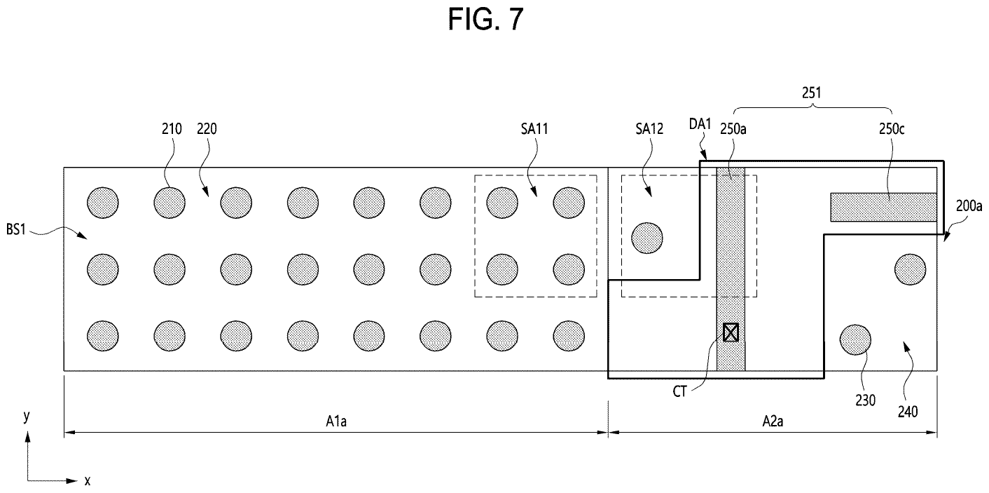

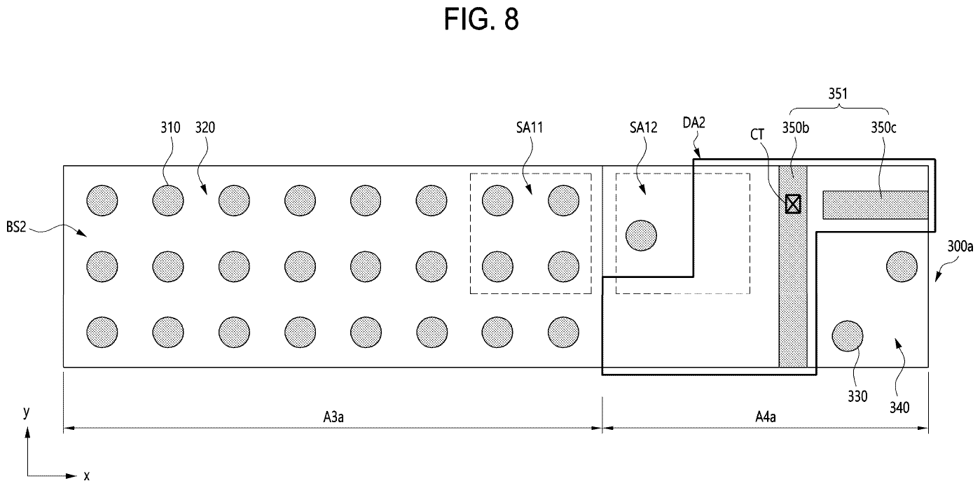

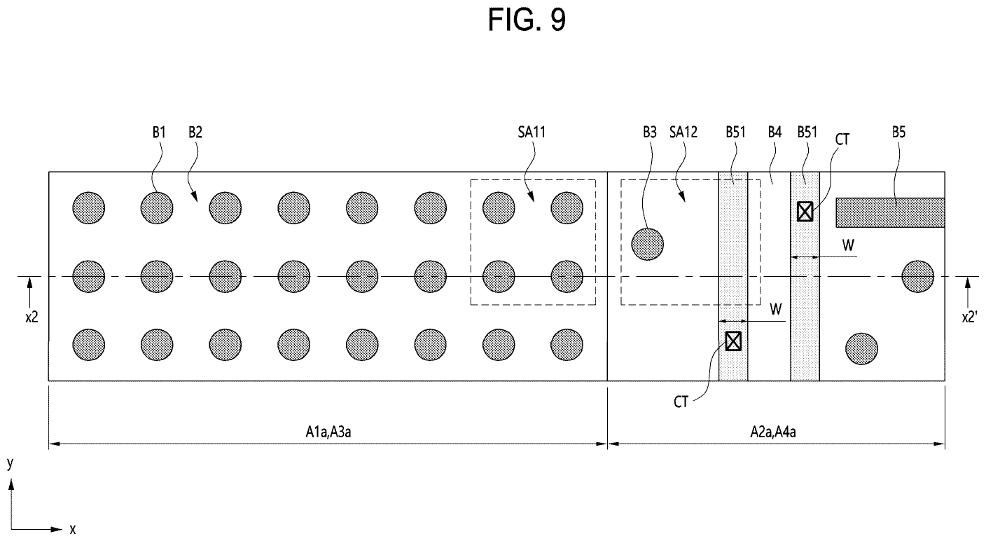

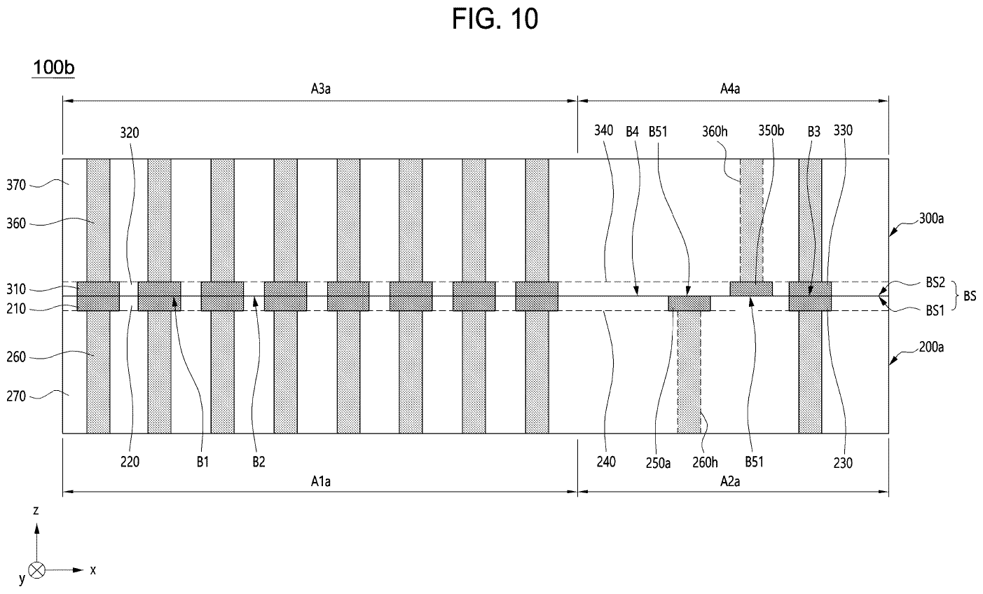

FIG. 7 is a plan view illustrating a first structure of a stack type semiconductor device in accordance with various embodiments of the present disclosure, FIG. 8 is a plan view illustrating a second structure of a stack type semiconductor device in accordance with other embodiments of the present disclosure, FIG. 9 is a plan view illustrating hybrid-bonded bonding surfaces of first and second structures in accordance with further embodiments of the present disclosure. FIG. 10 is a cross-sectional view taken along a line x2-x2′ in FIG. 9.

Referring to FIGS. 7 to 10, a stack type semiconductor device 100b may include a first structure 200a and a second structure 300a.

The first structure 200a may include a first bonding region Ala and a second bonding region A2a.

The first bonding region Ala may include a plurality of first bonding pads 210 and a first bonding insulation layer 220. The first bonding pads 210 and the first bonding insulation layer 220 may be substantially the same as the first bonding pads 210 and the first bonding insulation layer 220 in FIG. 2.

The second bonding region A2a may include a plurality of second bonding pads 230, a second bonding insulation layer 240 and a first bonding wiring 251. The second bonding pads 230 may be substantially the same as the second bonding pads 230 in FIG. 2.

In the disclosed embodiments, the first bonding wiring 251 may include a plurality of bonding wirings 250a and 250c. For example, numbers of the first bonding wirings 251 may be less than numbers of the first bonding wirings 250 in FIG. 2.

As shown in FIG. 8, the second bonding structure 300a may include a third bonding region A3a and a fourth bonding region A4a. The third bonding region A3a may include a plurality of third bonding pads 310 and a third bonding insulation layer 320. The third bonding pads 310 may correspond to the first bonding pads 210 in the first bonding region Ala. The third bonding insulation layer 320 may correspond to the first bonding insulation layer 220.

The fourth bonding region A4a may include a plurality of fourth bonding pads 330, a fourth bonding insulation layer 340 and a second bonding wiring 351.

In this embodiment, the fourth bonding pads 330 may have an arrangement substantially the same as the arrangement of the second bonding pads 230.

The second bonding wiring 351 may include a plurality of bonding wirings 350b and 350c. Numbers of the second bonding wirings 351 may be less than numbers of the second bonding wirings 350 in FIG. 3.

Therefore, the second bonding wiring 351 may include a portion 350c corresponding to the first bonding wiring 351 and a portion 350b not corresponding to the first bonding wiring 351. Similarly, the first bonding wiring 251 may include a portion 250c corresponding to the second bonding wiring 351 and a portion 250a not corresponding to the second bonding wiring 351.

As shown in the embodiments illustrated in FIGS. 9 and 10, when the first structure 200a is hybrid-bonded to the second structure 300a, a conductive layer versus a conductive layer bonding (B1, B3 and B5) is formed between the first bonding pads 210 and the third bonding pads 310, between the second bonding pad 230 and the fourth bonding pad 330 and between at least one 250c of the first bonding wirings and at least one of the second bonding wirings. Further, a dielectric layer versus a dielectric layer bonding (B2 and B4) may be formed between the first bonding insulation layer 220 and the third bonding insulation layer 320 and between the second bonding insulation layer 240 and the fourth bonding insulation layer 340.

A bonding surface BS between the second bonding region A2a of the first structure 200a and the fourth bonding region A4a of the second structure 300a may further include a conductive layer versus a dielectric layer (B51) formed between the first bonding wiring 250a and the fourth bonding insulation layer 340 and between the second bonding wiring 350b and the second bonding insulation layer 240.

As mentioned above, the numbers of the first bonding wirings 251 of the first structure 200a may be less than the numbers of example embodiments in FIG. 2. Thus, an occupying ratio of the first bonding insulation layer 220 by a unit area SA11 of the first bonding region Ala may be different from an occupying area of the second bonding insulation layer 240 by a unit area SA12 of the second bonding region A2a.

Similarly, the numbers of the second bonding wirings 351 of the second structure 300a may be less than the numbers of example embodiments in FIG. 3. Thus, an occupying ratio of the third bonding insulation layer 320 by a unit area SA11 of the third bonding region A3a may be different from an occupying area of the fourth bonding insulation layer 340 by a unit area SA12 of the fourth bonding region A4a.

However, when the hybrid-bonded first and second structures 200a and 300a is viewed from a side surface of the first and second structures 200a and 300a, the bonding area B51 between the second bonding wiring 350b and the second bonding insulation layer 240 and the bonding area B51 between the first bonding wiring 250a and the fourth bonding insulation layer 340 may be excluded from the bonding area B4 between the second bonding insulation layer 240 and the fourth bonding insulation layer 340.

Thus, the occupying area B2 of the first and third bonding insulation layers 220 and 320 in the first and third bonding regions A1a and A3a and the occupying area B4 of the second and fourth bonding insulation layers 240 and 340 in the second and fourth bonding regions A2a and A4a may be uniform within a prescribed range by the first and second bonding wirings 251 and 351.

That is, the occupying areas of the bonding insulation layers by the unit areas SA11 and SA12 in the stack type semiconductor devices 100 and 100a may correspond to an area of the dielectric layer versus an area of the dielectric layer bonding. Further, when ratios of the dielectric layer versus the dielectric layer bonding B2 and B4 by the unit areas SA11 and SA12 on a random position of the bonding surface BS may be uniform and no less than a prescribed range, this bonding may be determined to be normal.

Further, interconnections 260h and 360h shown by dotted lines in FIGS. 5 and 10 may be covered by insulating interlayers 270 and 370.

In another embodiment, the bonding wirings 251 and 351 may be selectively formed in the dummy regions DA1 and DA2 of the bonding structures, but the present invention is not limited thereto.

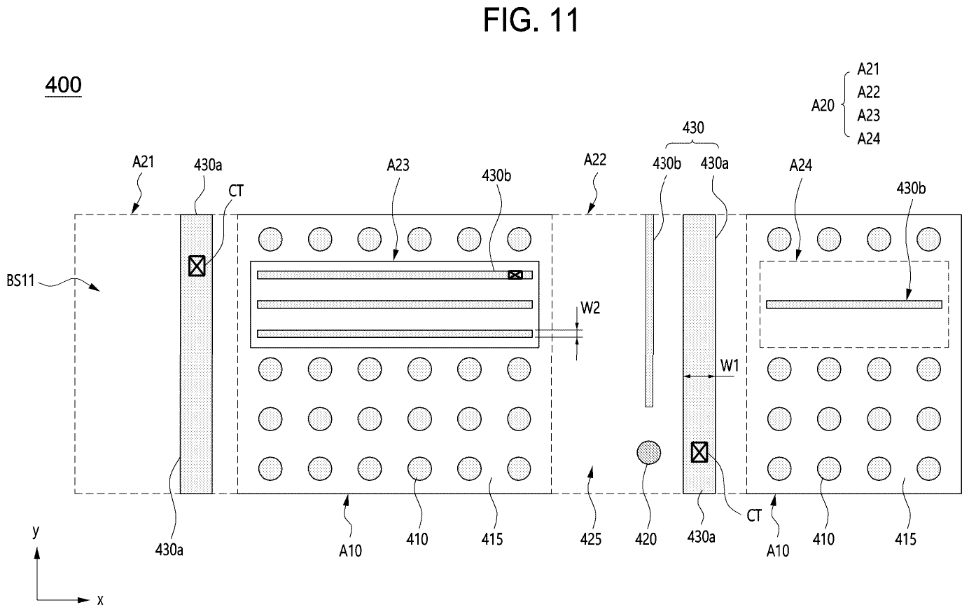

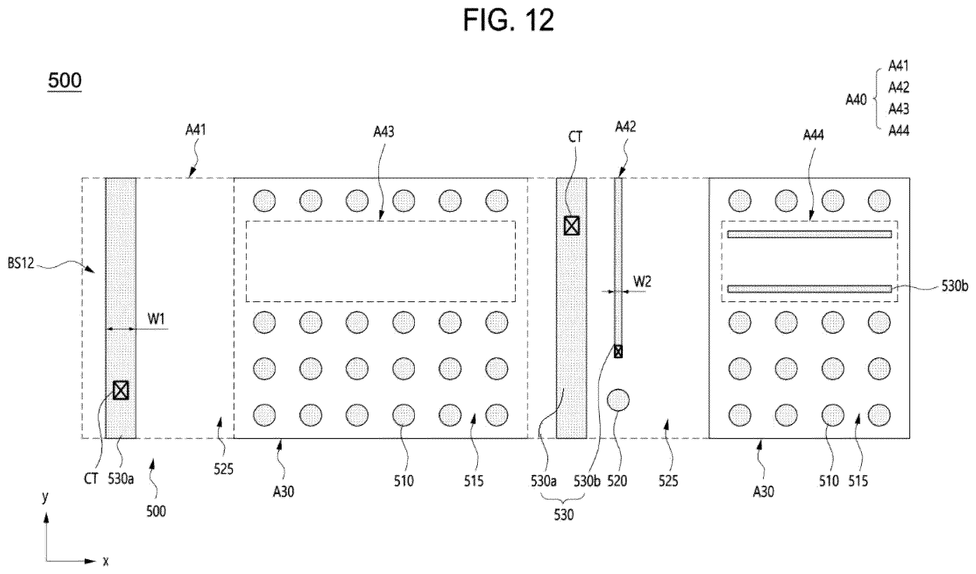

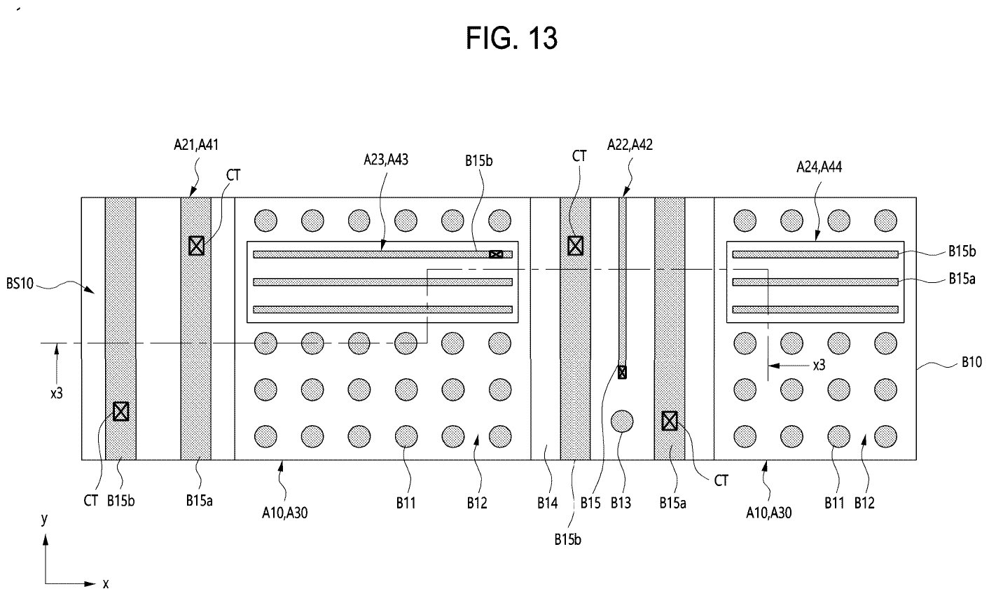

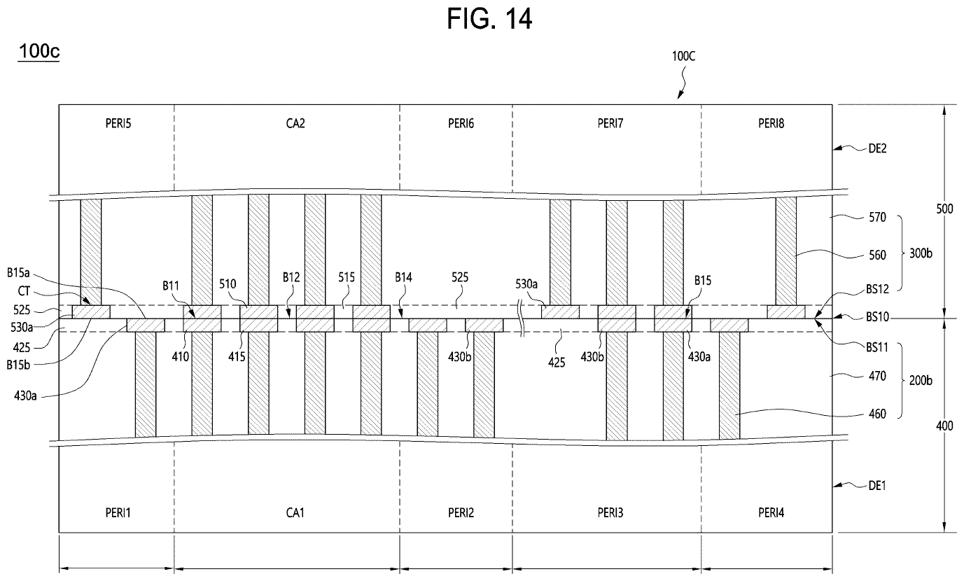

FIG. 11 is a plan view illustrating a first die of a stack type semiconductor device in accordance with various embodiments of the present disclosure, FIG. 12 is a plan view illustrating a second die of a stack type semiconductor device in accordance with other embodiments of the present disclosure, FIG. 13 is a plan view illustrating hybrid-bonded bonding surfaces of first and second dies in accordance with further embodiments of the present disclosure and FIG. 14 is a cross-sectional view taken along a line x3-x3′ in FIG. 13.

Referring to FIGS. 11 to 14, a stack type semiconductor device 100c may include a first die 400 and a second die 500.

The first die 400 may be a part of a first wafer. Alternatively, the first die 400 may be separated from the first wafer.

The first die 400 may include a first component DE1 and a first bonding structure 200b.

For example, as shown in FIG. 14, the first component DE1 may include at least one cell array region CA1 and at least one peripheral circuit region. The cell array region CA1 may include a plurality of densely arranged memory cells. The peripheral circuit region may include drive circuits and logic circuits configured to operate the memory cells. The peripheral circuit region may have an integration density lower than an integration density of the cell array region CA1. In other embodiments, the peripheral circuit region may include first to fourth sub-peripheral regions peri1, peri2, peri3 and peri4. The first and second sub-peripheral regions peri1 and peri2 may be positioned at both sides of the cell array region CA1. The third and fourth sub-peripheral regions peri3 and peri4 may be positioned in the cell array region CA1. The third and fourth sub-peripheral regions peri3 and peri4 may have a relatively low pattern density in the cell array region CA1. In FIG. 14, the cell array region CA1 may be substantially coplanar with the first to fourth sub-peripheral regions peri1, peri2, peri3 and peri4, but the present invention not limited thereto. Alternatively, in a peripheral under cell structure, at least one of the first to fourth sub-peripheral regions peri1, peri2, peri3 and peri4 may be positioned between the cell array region CA1 and the first bonding structure 200b.

The first bonding structure 200b may include a first bonding region A10 and a second bonding region A20.

The first bonding region A10 may include a plurality of first bonding pads 410 and a first bonding insulation layer 415 configured to isolate the first bonding pads 410 from each other. The first bonding pads 410 may be densely arranged to provide the cell array region CA1 of the first component DE1 with signals, addresses and/or power. Thus, the first bonding pads 410 having a set density may be arranged in the first bonding region A10. In further embodiments, the first bonding region A10 may correspond to the cell array region CA1.

The second bonding region A20 may include a region where the bonding pads having a density lower than the set density may be arranged. In further embodiments, the bonding pads in the second bonding region A20 may be second bonding pads 420.

In one embodiment, the second bonding region A20 may include first to fourth sub-bonding regions A21, A22, A23 and A24 corresponding to the first to fourth sub-peripheral regions peri1, peri2, peri3 and peri4. For example, the first and second sub-bonding regions A21 and A22 may be positioned at a side of the first bonding region A10. The third and fourth sub-bonding regions A23 and A24 may be positioned in the first bonding region A10.

For example, the third and fourth sub-bonding regions A23 and A24 may have areas smaller than areas of the first and second sub-bonding regions A21 and A22. Further, the first to fourth sub-bonding regions A21, A22, A23 and A24 may correspond to the first to fourth sub-peripheral regions peri1, peri2, peri3 and peri4 having a relatively high pattern density. Thus, the second bonding pads 420 having the density lower than the set density may be arranged in at least one of the first to fourth sub-bonding regions A21, A22, A23 and A24. For example, the second bonding pads 420 might not be arranged in at least one of the first to fourth sub-bonding regions A21, A22, A23 and A24.

The second bonding region A20, for example, the first to fourth sub-bonding regions A21, A22, A23 and A24 may include the second bonding pad 420, at least one of first bonding wirings 430 and a second bonding insulation layer 425.

The second bonding pads 420 may be arranged in at least one of the first to fourth sub-bonding regions A21, A22, A23 and A24. In this case, the second bonding pads 420 may have the density of no more than the set density. For example, a pitch between the second bonding pads 420 may be greater than a pitch between the first bonding pads 410.

The first bonding wiring 430 may include a plurality of first bonding wirings 430a and 430b having various widths. For example, the width of the first bonding wirings 430a and 430b may be determined in accordance with the areas of the first to fourth sub-bonding regions A21, A22, A23 and A24. In the embodiments shown in FIG. 11, the first and second sub-bonding regions A21 and A22 having relatively large areas may include at least one of the first bonding wiring 430a having a relatively wide width w1 and the first bonding wiring 430b having a relatively narrow width w2.

The third and fourth sub-bonding regions A23 and A24 having relatively small areas may include at least one of the first bonding wiring 430b having the relatively narrow width w2.

The first bonding wiring 430a having the relatively wide width w1 may be used for a power transmission wiring or a reservoir capacitor. The first bonding wiring 430b having the relatively narrow width w2 may transmit the signals or the addresses to the first component DE1.

That is, the first bonding wirings 430a and 430b having various widths, various extending directions and various numbers may be integrated in the first to fourth sub-bonding regions A21, A22, A23 and A24 in consideration of the shapes and numbers of the first to fourth sub-bonding regions A21, A22, A23 and A24. For example, the first bonding wiring 430a may be integrated in a selected portion of the first sub-bonding region A21 along the y-direction. The first bonding wirings 430a and 430b extended in the y-direction may be arranged spaced apart from each other by a gap in a selected portion of the second sub-bonding region A22. The first bonding wiring 430b extended in the x-direction may be arranged spaced apart from each other by a gap in the third sub-bonding region A23. The first bonding wiring 430b extended in the x-direction may be arranged in a selected portion of the fourth sub-bonding region A24.

Further, the first bonding pads 410 and the first bonding insulation layer 415 in the first bonding region A10, and the second bonding pads 420, the second bonding insulation layer 425 and the first bonding wirings 430a and 430b in the second bonding region A20 may be exposed toward the first bonding surface BS11 of the first bonding structure 200b.

The second die 500 may be a part of a second wafer. Alternatively, the second die 500 may be separated from the second wafer.

The second die 500 may include a second component DE2 and a second bonding structure 300b.

For example, as shown in FIG. 14, the second component DE2 may include at least one cell array region CA2 and at least one peripheral circuit region. The peripheral circuit region may include fifth to eighth sub-peripheral regions peri5, peri6, peri7 and peri8. The fifth and eighth sub-peripheral regions peri5, peri6, peri7 and peri8 may correspond to the first to fourth sub-peripheral regions peri1, peri2, peri3 and peri4, respectively.

The second bonding structure 300b may include a third bonding region A30 and a fourth bonding region A40. The third bonding region A30 may correspond to the cell array region CA2 of the second component DE2 and the first bonding region A10. The fourth bonding region A40 may correspond to the fifth to eighth sub-peripheral regions peri5, peri6, peri7 and peri8 of the second component DE2 and the second bonding region A20.

The third bonding region A30 may include a plurality of third bonding pads 510 and a third bonding insulation layer 515 configured to isolate the third bonding pads 510 from each other. The third bonding pads 510 may correspond to the first bonding pads 410.

In various embodiments, the fourth bonding region A40 may include fifth to eighth sub-bonding regions A41, A42, A43 and A44. The fifth to eighth sub-bonding regions A41, A42, A43 and A44 may face the fifth to eighth sub-peripheral regions peri5, peri6, peri7 and peri8 and the first to fourth sub-bonding regions A21, A22, A23 and A24 of the first bonding structure 200b. The fifth and sixth sub-bonding regions A41 and A42 may be positioned at a side of the third bonding region A30. The seventh and eighth sub-bonding regions A43 and A44 may be positioned in a dummy region of the third bonding region A30. For example, the seventh and eighth sub-bonding regions A43 and A44 may have an area smaller than an area of the fifth and sixth sub-bonding regions A41 and A42.

When the fourth bonding pads 520 may be arranged in at least one of the fifth to eighth sub-bonding regions A41, A42, A43 and A44, the fourth bonding pads 520 may have a density lower than the set density. The fourth bonding pads 520 may correspond to or not the second bonding pads 420 of the first die 400.

The second bonding wiring 530 having various widths, various lengths, various extending directions and various numbers may be arranged in the fifth to eighth sub-bonding regions A41, A42, A43 and A44 in consideration of the shapes and numbers of the fifth to eighth sub-bonding regions A41, A42, A43 and A44. The second bonding wiring 530 may include a second bonding wiring 530a having a relatively wide width w1 and a second bonding wiring 530b having a relatively narrow width w2, but the present invention is not limited thereto. The second bonding wiring 530a having the relatively wide width w1 and the second bonding wiring 530b having the relatively narrow width w2 may be all integrated in at least one of the fifth to eighth sub-bonding regions A41, A42, A43 and A44, or selectively integrated in the fifth to eighth sub-bonding regions A41, A42, A43 and A44. The second bonding wirings 530a and 530b may be extended in a same direction or different directions. The second bonding wirings 530a and 530b may be arranged at a position corresponding to the first bonding wirings 430a and 430b. Alternatively, the second bonding wirings 530a and 530b may correspond to the second bonding insulation layer 425 of the first die 400.

In one embodiment, the second bonding wirings 530a and 530b may be used for a residual conductive wiring similarly to the first bonding wirings 430a and 430b to provide the second component DE2 with power, electrical signals and addresses from the first component 400 or an external device.

For example, the second bonding wiring 530a extended in the y-direction may be integrated in a selected portion of the fifth sub-bonding region A41. The second bonding wirings 430a and 430b extended in the y-direction may be arranged spaced apart from each other by a gap in a selected portion of the sixth sub-bonding region A42. The second bonding wiring 430b may not be arranged in the seventh sub-bonding region A43. The second bonding wiring 530b extended in the x-direction may be arranged in a selected portion of the eighth sub-bonding region A44.

Further, the third bonding pads 510 and the third bonding insulation layer 515 in the third bonding region A30, and the fourth bonding pads 520, the fourth bonding insulation layer 525 and the first bonding wirings 430a and 430b in the fourth bonding region A40 may be exposed toward the second bonding surface BS12 of the second bonding structure 300b.

As shown in FIGS. 13 and 14, the first die 400 and the second die 500 may be stacked such that the first bonding surface BS11 and the second bonding surface BS12 face each other. The first die 400 and the second die 500 may then be hybrid-bonded to each other.

The bonding B11 may be a conductive layer versus a conductive layer bonding between the first bonding pad 410 and the third bonding pad 510. The bonding B12 may be a dielectric layer versus a dielectric layer bonding between the first bonding insulation layer 415 and the third bonding insulation layer 515. The bonding B13 may be a conductive layer versus a conductive layer bonding between the second bonding pad 420 and the fourth bonding pad 520. The bonding B14 may be a dielectric layer versus a dielectric layer bonding between the second bonding insulation layer 425 and the fourth bonding insulation layer 525. The bonding B15 may be a conductive layer versus a conductive layer bonding between the first bonding wiring 430 and the second bonding wiring 530. The bonding B15a may be a conductive layer versus a dielectric layer bonding between the first bonding wiring 430a or 430b and the fourth bonding insulation layer 525. The bonding B15b may be a conductive layer versus a dielectric layer bonding between the second bonding wiring 530a or 530b and the second bonding insulation layer 425.

The first and second bonding wirings 430a, 430b, 530a and 530b may be electrically connected with conductive terminals of the first and second components DE1 and DE2, which may be integrated in a corresponding die 400 or 500, through the interconnections 460 and 560. Thus, the first and second components DE1 and DE2 may receive the electrical signals such as an operation voltage, an address and a power, which may be provided from the external device, through the bonding wirings 430 and 530 as well as the bonding pads 410, 420, 510 and 520.

Further, the bonding wirings 430 and 530 may be used for a redistribution layer. For example, the first bonding wire 430 may be electrically connected to the first bonding pad 410. The first bonding wire 430 may be used as a part of the redistribution layer configured to transmit the voltage from the first bonding pad 410 to the conductive terminal of the first component DE1. Further, the bonding wirings 430 and 530 may be operated as a reservoir capacitor configured to stabilize the power of the first and second components DE1 and DE2.

The bonding wirings 430 and 530 may be formed in the dummy region such as the second and fourth bonding regions where the bonding pads may be coarsely arranged in place of a conventional dummy pad to which an electrical signal may not be provided. Thereby, the bonding wirings 430 and 530 may improve the electrical characteristics of the stack type semiconductor device. Further, the bonding wirings 430 and 530 may improve the bonding uniformity in place of the dummy pad.

In another embodiment, the first and second bonding wirings 430 and 530 may be extended in the x-direction or the y-direction, but the present invention is not limited thereto. The directions of the first and second bonding wirings 430 and 530 may be changed in accordance with the size of the dummy region, the occupying ratio of the bonding insulation layer by the unit area in the bonding surface BS10, i.e., the bonding ratio between the dielectric layer and the dielectric layer and a signal transmission path.

Further, the interconnections may include the TSV, but the present invention is not limited thereto. The interconnections may be changed in accordance with multi-layered metal wirings and a plurality of vertical plugs between the multi-layered metal wirings.

According to various embodiments, the at least one bonding wiring may receive and transmit the electrical signal from/to the dummy region where the bonding pads may be coarsely arranged. The signals transmitted through the bonding wiring may improve the signal transmission characteristic and the electrical characteristic of the stack type semiconductor device. Further, because the bonding wiring may be hybrid-bonded to the bonding pad, the occupying area of the insulation layer on the bonding surface of the stack type semiconductor device may be controlled to improve the bonding uniformity of the stack type semiconductor device.

The above described embodiments of the present invention are intended to illustrate and not to limit the present invention. Various alternatives and equivalents are possible. The invention is not limited by the embodiments described herein. Nor is the invention limited to any specific type of semiconductor device. Other additions, subtractions, or modifications are apparent in view of the present disclosure. Furthermore, the embodiments may be combined to form additional embodiments.

What is claimed is:

1. A bonding structure including a component and a bonding surface, the bonding structure comprising:
the bonding surface including a first bonding region, a second bonding region and at least one bonding wiring,
wherein the first bonding region includes a plurality of first bonding pads and a first bonding insulation layer, the first bonding pads have a first density distributed in the first bonding region, and the first bonding insulation layer is positioned between the first bonding pads,
wherein the second bonding region includes a plurality of second bonding pads and a second bonding insulation layer, the second bonding pads have a second density lower than the first density and are distributed in the second bonding region, and the second bonding insulation layer is positioned between the second bonding pads, and
wherein the at least one bonding wiring is arranged at the second bonding region, and the at least one bonding wiring is configured to receive and transfer an external voltage to the component.

2. The bonding structure of claim 1, further comprising a plurality of interconnections configured to electrically connect the first bonding pads, the second bonding pads and the bonding wiring with conductive terminals of the component.

3. The bonding structure of claim 1, wherein the bonding wiring is arranged in the second bonding region to maintain a percentage of the second bonding insulation layer to a unit area of the second bonding region within a prescribed range.

4. The bonding structure of claim 3, wherein the percentage of the first bonding insulation layer to the unit area of the first bonding region is maintained within the prescribed range.

5. The bonding structure of claim 4, wherein the prescribed range is an occupying area of the first bonding insulation layer or the second bonding insulation layer by the unit area and the prescribed range is from 50% to about 90% of the unit area.

6. The bonding structure of claim 1, wherein the voltage provided to the bonding wiring comprises at least one or more of a power, an operation signal and an address provided to the component.

7. The bonding structure of claim 1, wherein the second bonding region comprises a dummy region where the second bonding pads are not arranged, and a shape and a number of the at least one bonding wiring are determined based on a shape and a size of the dummy region.

8. A stack type semiconductor device comprising:
a first structure including a first bonding region and a second bonding region, the first bonding region including a plurality of first bonding pads and a first bonding insulation layer positioned between the first bonding pads, and the second bonding region including at least one second bonding pad, a second bonding insulation layer configured to insulate the second bonding pad, and at least one first bonding wiring positioned in the second bonding insulation layer; and
a second structure including a third bonding region and a fourth bonding region, the third bonding region including a plurality of third bonding pads hybrid-bonded to the first bonding pads, and a third bonding insulation layer hybrid-bonded to the first bonding insulation layer,
wherein the fourth bonding region includes a fourth bonding pad hybrid-bonded to the second bonding pad, a fourth bonding insulation layer hybrid-bonded to at least one of the second bonding insulation layer and the first bonding wiring, and
wherein at least one second bonding wiring is hybrid-bonded to at least one of the at least one first bonding wiring and the second bonding insulation layer.

9. The stack type semiconductor device of claim 8, wherein an area ratio between the first bonding insulation layer and the third bonding insulation layer and an area ratio between the second bonding insulation layer and the fourth bonding insulation layer are within a prescribed range.

10. The stack type semiconductor device of claim 9, wherein the prescribed range comprises a bonding occupying ratio between the first bonding insulation layer and the third bonding insulation layer or between the second bonding insulation layer and the fourth bonding insulation layer, and the bonding occupying ratio is based on a unit area on a bonding surface between the first structure and the second structure, and the prescribed range is from 50% to about 90% of the unit area.

11. The stack type semiconductor device of claim 8, further comprising:
a first component including a plurality of conductive terminals electrically connected with the first structure; and
a second component including a plurality of conductive terminals electrically connected with the second structure.

12. The stack type semiconductor device of claim 11, wherein the first structure comprises a plurality of first interconnections configured to connect the first bonding pads, the second bonding pads and the first bonding wiring with the conductive terminals of the first component.

13. The stack type semiconductor device of claim 12, wherein the at least one first bonding wiring receives a voltage corresponding to a power, and at least one of an operation signal and the voltage is transmitted to the conductive terminals of the first component through the first interconnections.

14. The stack type semiconductor device of claim 11, wherein the second structure comprises a plurality of second interconnections configured to connect the third bonding pads, the fourth bonding pads and the second bonding wiring with the conductive terminals of the second component.

15. The stack type semiconductor device of claim 14, wherein the second bonding wiring receives at least one of a voltage corresponding to a power, an operation signal, and an address, and the voltage is transmitted to the conductive terminals of the second component through the second interconnections.

16. The stack type semiconductor device of claim 11, wherein each of the first and second components comprises a cell array region and a peripheral circuit region, the second bonding region corresponds to the peripheral circuit region of the first component, and the fourth bonding region corresponds to the peripheral circuit region of the second component.

17. A stack type semiconductor device including a first die and a second die hybrid-bonded to the first die, the stack type semiconductor device comprising:
the first die including a first bonding region, a second bonding region and at least one first bonding wiring,
wherein bonding pads having a first density are arranged in the first bonding region,
wherein the second bonding region includes a first region where the bonding pads having a second density lower than the first density are arranged and a second region where the bonding pads are not arranged, and
wherein the at least one first bonding wiring is arranged in the second region and is hybrid-bonded to the second die, and the at least one first bonding wiring receives and transmits an electrical signal.

18. The stack type semiconductor device of claim 17, wherein the second die includes a third bonding region, a fourth bonding region and at least one second bonding wiring,
wherein the third bonding region comprises bonding pads hybrid-bonded to the bonding pads in the first bonding region;
wherein the fourth bonding region comprises bonding pads having a density lower than a density of the bonding pads in the third bonding region, and
wherein the at least one second bonding wiring is arranged in the fourth region and is hybrid-bonded to the second bonding region, and the at least one second bonding wiring receives and transmits the electrical signal.

19. The stack type semiconductor device of claim 18, wherein each of the first to fourth bonding regions further comprises a bonding insulation layer.

20. The stack type semiconductor device of claim 19, wherein the first bonding wiring is hybrid-bonded to at least one of a) the at least one second bonding wiring and b) the bonding insulation layer in the fourth boding region, and the second bonding wiring is hybrid-bonded to at least one of a) the at least one first bonding wiring and b) the bonding insulation layer in the second bonding region.
